(19) United States
(12) Patent Application Publication
(10) Pub. No.: US 2026/0318960 A1
(43) Pub. Date: Oct. 15, 2026

(54) CURRENT-MEASUREMENT SEMICONDUCTOR DEVICE

(71) Applicant: Nuvoton Technology Corporation Japan, Kyoto (JP)

(72) Inventor: Hitoshi KOBAYASHI, Kyoto (JP)

(21) Appl. No.: 19/695,366

(22) Filed: Jun. 2, 2026

Related U.S. Application Data
(63) Continuation of application No. PCT/JP2024/041234, filed on Nov. 21, 2024.

(30) Foreign Application Priority Data
Dec. 11, 2023 (JP) 2023-208792

(51) Int. Cl. G01R 19/165; G01R 19/32; G01R 31/374; G01R 31/387; G01R 31/392; H01M 10/0525

(52) U.S. Cl. CPC G01R 19/16528; G01R 19/16504; G01R 19/32; G01R 31/374; G01R 31/387; G01R 31/392; H01M 10/0525

(57) ABSTRACT

A current-measurement semiconductor device that measures current flowing through a shunt resistor included in a measurement target device. The current-measurement semiconductor device includes: a first current-measurement circuit that measures the current flowing through the shunt resistor by detecting a voltage across the shunt resistor; and a second current-measurement circuit that includes a coreless magnetic sensor, and measures the current flowing through the shunt resistor using the coreless magnetic sensor.

### CROSS REFERENCE TO RELATED APPLICATIONS

This is a continuation application of PCT International Patent Application No. PCT/JP 2024/041234 filed on Nov. 21, 2024, designating the United States of America, which is based on and claims priority of Japanese Patent Application No. 2023-208792 filed on Dec. 11, 2023. The entire disclosures of the above-identified applications, including the specifications, drawings and claims are incorporated herein by reference in their entirety.

### FIELD

The present disclosure relates to a current-measurement semiconductor device, and particularly to a current-measurement semiconductor device that measures the current flowing through a shunt resistor included in a measurement target device.

### BACKGROUND

Conventionally, current measurement for lithium-ion batteries included in electric vehicles has widely used magnetic sensor-type current-measurement circuits with cores (hereinafter, referred to as the core-based magnetic sensor method). However, although the core-based magnetic sensor method can measure low currents, it is difficult to achieve a wide dynamic range from low currents to high currents due to hysteresis or magnetic saturation of the magnetic core. The current measurement accuracy of core-based magnetic sensors is typically around ±1%.

In contrast, coreless magnetic sensors, without cores, do not suffer from magnetic saturation and can measure currents in higher-current regions. However, those coreless magnetic sensors cannot achieve high measurement accuracy due to disturbance noise and their installation position. For this reason, coreless magnetic sensors require adjustment after installation, and are therefore rarely used for current measurement of lithium-ion batteries.

In recent years, due to improvements in electric vehicle performance, current measurement for lithium-ion batteries requires, in addition to current measurement covering a range of from approximately 10 mA to 100 mA when the vehicle is stationary, current measurement covering a range of from approximately 1,000 A to 2,000 A at the maximum. Moreover, in order to highly accurately calculate the state of charge (SOC) of lithium-ion batteries, Coulomb-counting in the current measurement requires current measurement accuracy of around ±0.1%.

Accordingly, current measurement for electric vehicles is increasingly shifting from the core-based magnetic sensor method to shunt resistor-based current-measurement circuits (hereinafter, referred to as the shunt current method).

However, in the shunt current method, when a short-mode failure occurs in a shunt resistor through which the battery current directly flows, the measured current value will, in principle, appear lower, and thus such a failure is unable to be detected. In other words, a short-mode failure in the shunt current method is unable to detect overcurrent in the dangerous range that can lead to lithium-ion battery ignition or explosion, making it difficult to claim that the method provides fail-safe protection. Therefore, functional-safety measures, such as providing redundancy by arranging a plurality of current-measurement circuits that use shunt resistors, are essential.

In view of the above, a redundancy method has been conventionally proposed in which two shunt resistors having different resistance values are connected in series to avoid occurrences of common-cause failures (see Patent Literature (PTL) 1).

### CITATION LIST

### Patent Literature

PTL 1: International Publication No. 2016-047010

### SUMMARY

### Technical Problem

However, even if the shunt resistors have different resistance values as in PTL 1, redundancy implemented using the same shunt-resistor technique cannot be said to preclude the possibility of common-cause failures in which the same failure mode occurs simultaneously due to overcurrent flowing through the battery.

In view of the above, the present disclosure provides a current-measurement semiconductor device that measures the current flowing through a shunt resistor and reduces common-cause failures.

### Solution to Problem

In order to provide the above-described current-measurement semiconductor device, a current-measurement semiconductor device according to one embodiment of the present disclosure is a current-measurement semiconductor device that measures current flowing through a shunt resistor included in a measurement target device. The current-measurement semiconductor device includes: a first current-measurement circuit that measures the current flowing through the shunt resistor by detecting a voltage across the shunt resistor; and a second current-measurement circuit that includes a coreless magnetic sensor, and measures the current flowing through the shunt resistor using the coreless magnetic sensor.

### Advantageous Effects

According to the present disclosure, a current-measurement semiconductor device that measures the current flowing through a shunt resistor and reduces common-cause failures is provided.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a circuit block diagram illustrating the configuration of a current-measurement semiconductor device according to an embodiment.

FIG. 2A is a diagram illustrating the external appearance of an implementation example of the current-measurement semiconductor device according to the embodiment.

FIG. 2B is a diagram illustrating a layout example of main circuit elements in the current-measurement semiconductor device according to the embodiment.

FIG. 3 is a diagram illustrating current-voltage characteristics of a shunt resistor included in a measurement target device and a coreless magnetic sensor included in the current-measurement semiconductor device, and corrections performed by the current-measurement semiconductor device.

FIG. 4 is a flowchart illustrating operation performed by the current-measurement semiconductor device according to the embodiment.

FIG. 5 is a flowchart illustrating operation performed by the current-measurement semiconductor device according to the embodiment for detecting an anomaly in the shunt resistor.

FIG. 6 is a flowchart illustrating operation performed by the current-measurement semiconductor device according to the embodiment for detecting an anomaly in the measurement target device.

### DESCRIPTION OF EMBODIMENT

### Outline and Advantageous Effects of the Disclosure

In one example of the present disclosure, a current-measurement semiconductor device (hereinafter, also simply referred to as the “semiconductor device”) that measures the current flowing through a shunt resistor includes a coreless magnetic sensor. By implementing a coreless current-sensor circuit in this manner, the semiconductor device enables the implementation of a redundant current-measurement circuit in which common-cause failures are reduced.

More specifically, in one example of the present disclosure, a second current-measurement circuit that measures the current using the coreless magnetic sensor is used in a high-current region in which the shunt resistor is unable to detect the current. In other words, a magnetic-sensor dead zone is established for a micro-current region in which the coreless magnetic sensor circuit is unable to measure the current, and the second current-measurement circuit is used such that measurement value measured by the second current-measurement circuit in the magnetic-sensor dead zone is disregarded (i.e., only the measurement value measured by the shunt resistor is adopted).

Moreover, to correct the temperature dependence of the coreless magnetic sensor and the shunt resistor, the semiconductor device includes temperature-measurement circuits for the coreless magnetic sensor and the shunt resistor. With this, the temperature dependence of the first current-measurement circuit and the second current-measurement circuit can be corrected.

Since a typical coreless magnetic sensor consists solely of a semiconductor device, the sensor is very compact and easy to place. However, as for the coreless magnetic sensor, the density of magnetic flux produced by the flowing current varies depending on disturbance noise and the distance between the magnetic sensor and measurement target wiring, such as a bus bar. Accordingly, to use the coreless magnetic sensor for measurement of the absolute value of the current, it is essential to perform correction on the coreless magnetic sensor after the placement. Moreover, because micro-current detection is also difficult, coreless magnetic sensors are rarely used for current measurement of lithium-ion batteries.

In view of the above, the present disclosure provides a semiconductor device that includes, within the same semiconductor device, a first current-measurement circuit that measures current using a shunt resistor and a second current-measurement circuit that measures the current using a coreless magnetic sensor, so as to enable correction of the second current-measurement circuit that measures the current using the coreless magnetic sensor based on a measurement value of the first current-measurement circuit that measures the current using the shunt resistor.

Furthermore, factors causing a short-mode failure in the shunt resistor are mainly due to high current, and conditions that lead to lithium-ion battery ignition or explosion also involve high current (overcurrent).

Accordingly, even though the coreless magnetic sensor has difficulty detecting micro-currents, a short-mode failure in the shunt resistor can be detected by comparing, only during a period during which high current flows, the measurement value of the first current-measurement circuit that measures the current using a shunt resistor with the measurement value of the second current-measurement circuit that measures the current using a coreless magnetic sensor.

In addition, since the semiconductor device according to the present disclosure which includes a current-measurement circuit that measures the current using a shunt resistor is provided in the vicinity of the shunt resistor, the coreless magnetic sensor on the semiconductor device can be optimally positioned to detect magnetic flux produced by the current flowing through the shunt resistor.

Furthermore, the semiconductor device according to the present disclosure can be readily provided with a temperature-measurement circuit. Accordingly, the temperature dependence of the coreless magnetic sensor on the semiconductor device and the shunt resistor on the measurement target device can be readily corrected.

### Embodiment

Hereinafter, an embodiment according to the present disclosure will be described in detail with reference to the drawings. Note that the embodiments described below each show a specific example of the present disclosure. The numerical values, shapes, materials, circuit elements, the arrangement and connection of the circuit elements, signal waveforms, signal timings, etc. presented in the embodiments below are mere examples and are not intended to limit the present disclosure. Moreover, the drawings do not necessarily provide strictly accurate illustrations. Throughout the drawings, the same reference sign is given to substantially the same element, and redundant description is omitted or simplified. Moreover, the term “connection” means an electrical connection, and includes not only the case where two circuit elements are directly connected but also the case where two circuit elements are indirectly connected with another circuit element interposed therebetween.

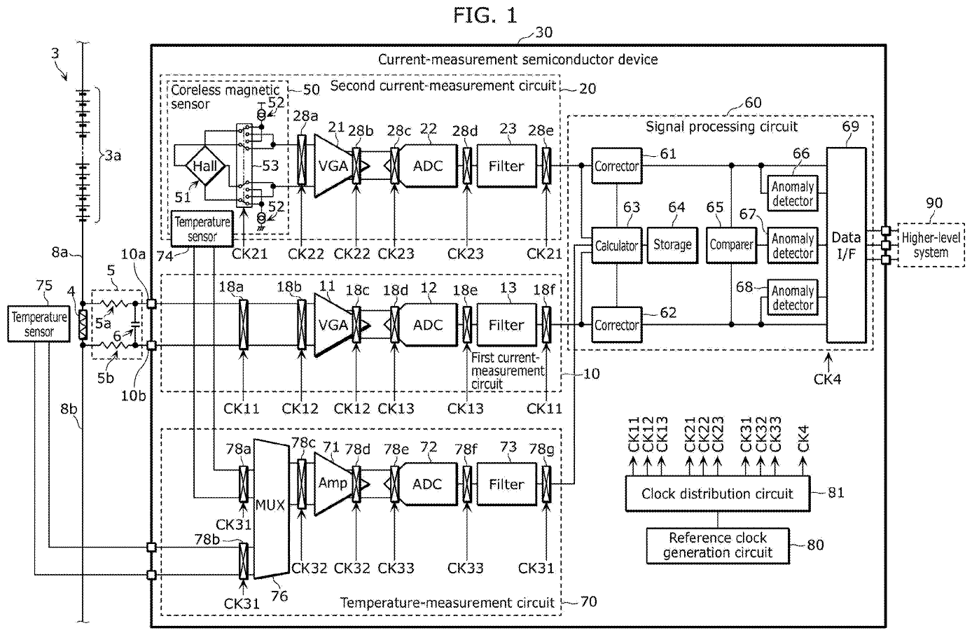

FIG. 1 is a circuit block diagram illustrating the configuration of current-measurement semiconductor device 30 according to the embodiment. Note that the present diagram also illustrates measurement target device 3 that is a current-measurement target to be measured by current-measurement semiconductor device 30, higher-level system 90 to which a measurement result obtained by current-measurement semiconductor device 30 is transmitted, etc.

Current-measurement semiconductor device 30 is a single semiconductor device that measures the current flowing through shunt resistor 4 included in measurement target device 3 to transmit the measurement to higher-level system 90. For example, with the exception of temperature sensor 75, current-measurement semiconductor device 30 is implemented either as a single-chip semiconductor or as a multi-chip semiconductor in which a plurality of chips are combined in a single package. Note that, as with the other circuit components, temperature sensor 75 may be provided inside the single-chip semiconductor or inside the single package.

Measurement target device 3 is, in the present embodiment, a lithium-ion battery system for electric vehicles. Measurement target device 3 includes lithium-ion battery cell stack 3a, shunt resistor 4 connected in series with cell stack 3a, bus bars 8a and 8b connecting cell stack 3a and shunt resistor 4, and the like. Higher-level system 90 is, for example, an electronic control unit (ECU) or the like included in the electric vehicle.

Current-measurement semiconductor device 30 includes: first current-measurement circuit 10 that measures the current flowing through shunt resistor 4 included in measurement target device 3 by detecting the voltage across shunt resistor 4; second current-measurement circuit 20 that redundantly measures the current flowing through shunt resistor 4 using coreless magnetic sensor 50; temperature-measurement circuit 70 that measures the temperatures of coreless magnetic sensor 50 and shunt resistor 4; signal processing circuit 60 that corrects measurement values of first current-measurement circuit 10 and second current-measurement circuit 20, detects anomalies, and the like; and reference clock generation circuit 80 and clock distribution circuit 81 for supplying clock signals to each circuit element.

Reference clock generation circuit 80 generates a single reference clock. Clock distribution circuit 81, for example, divides the reference clock from reference clock generation circuit 80 to supply, as illustrated, reference clocks CK11 to CK13, CK21 to CK23, CK31 to CK33, and CK4 to chopper circuits 18a to 18f and the like.

First current-measurement circuit 10 measures the current flowing through shunt resistor 4 included in measurement target device 3. First current-measurement circuit 10 includes input terminals 10a and 10b, differential variable gain amplifier (VGA) 11, analog-to-digital converter (ADC) 12 such as a delta-sigma ADC, filter 13 such as a decimation filter, and chopper circuits 18a to 18f. Note that filter circuit 5 (chip resistors 5a and 5b, and chip capacitor 6) for noise reduction is provided between shunt resistor 4 and input terminals 10a and 10b.

The voltage produced across shunt resistor 4 is first filtered by filter circuit 5 to reduce noise. The signal then passes through chopper circuits 18a and 18b and is input to variable gain amplifier 11. After amplification by variable gain amplifier 11, the signal passes through chopper circuits 18c and 18d and is input to analog-to-digital converter 12. After being converted into a digital signal sequence by analog-to-digital converter 12, the signals pass through chopper circuit 18e and are input to filter 13, where the signals are averaged and converted into parallel signals. Finally, the parallel signals pass through chopper circuit 18f and are output as a measurement value.

Chopper circuits 18a and 18f chop the signal in synchronization with reference clock CK11 from clock distribution circuit 81 to globally reduce offsets that may arise mainly from the signal processing in first current-measurement circuit 10. Chopper circuits 18b and 18c chop the differential signal in synchronization with reference clock CK12 from clock distribution circuit 81 to switch between positive and negative polarities, and chopper circuits 18d and 18e chop the differential signal in synchronization with reference clock CK13 from clock distribution circuit 81 to switch between positive and negative polarities, thereby respectively reducing 1/f noise that may arise mainly from the signal processing in variable gain amplifier 11 and analog-to-digital converter 12.

Second current-measurement circuit 20 uses coreless magnetic sensor 50 to redundantly measure the current flowing through shunt resistor 4. Second current-measurement circuit 20 includes coreless magnetic sensor 50, differential variable gain amplifier (VGA) 21, analog-to-digital converter (ADC) 22 such as a delta-sigma ADC, filter 23 such as a decimation filter, and chopper circuits 28a to 28e. Coreless magnetic sensor 50 includes hall element 51, current sources 52 that apply current to Hall element 51, and switching circuit 53 that switches connection between (i) Hall element 51 and (ii) current sources 52 and chopper circuit 28a.

The voltage produced in Hall element 51 passes through switching circuit 53 and chopper circuit 28a and is input to variable gain amplifier 21. After amplification by variable gain amplifier 21, the signal passes through chopper circuits 28b and 28c and is input to analog-to-digital converter 22. After being converted into a digital signal sequence by analog-to-digital converter 22, the signals pass through chopper circuit 28d and are input to filter 23, where the signals are averaged and converted into parallel signals. Finally, the parallel signals pass through chopper circuit 28e and are output as a measurement value.

Switching circuit 53 switches, for Hall element 51, the current application and voltage measurement location in synchronization with reference clock CK21 from clock distribution circuit 81, and chopper circuit 28e chops the signal in synchronization with reference clock CK21 from clock distribution circuit 81 to globally reduce offsets that may arise mainly from the signal processing in second current-measurement circuit 20. Chopper circuits 28a and 28b chop the differential signal in synchronization with reference clock CK22 from clock distribution circuit 81 to switch between positive and negative polarities, and chopper circuits 28c and 28d chop the differential signal in synchronization with reference clock CK23 from clock distribution circuit 81 to switch between positive and negative polarities, thereby respectively reducing 1/f noise that may arise mainly from the signal processing in variable gain amplifier 21 and analog-to-digital converter 22.

Temperature-measurement circuit 70 measures the temperatures of coreless magnetic sensor 50 and shunt resistor 4. Temperature-measurement circuit 70 includes temperature sensors 74 and 75, multiplexer (MUX) 76, differential amplifier (Amp) 71, analog-to-digital converter (ADC) 72 such as a delta-sigma ADC, filter 73 such as a decimation filter, and chopper circuits 78a to 78g. Temperature sensor 74 is provided in contact with or in the vicinity of coreless magnetic sensor 50, and detects the temperature of coreless magnetic sensor 50. Temperature sensor 74 is, for example, a semiconductor temperature sensor such as a diode. Temperature sensor 75 is provided in contact with or in the vicinity of shunt resistor 4, and detects the temperature of shunt resistor 4. Temperature sensor 75 is, for example, a thermistor or the like.

The voltage corresponding to the temperature of Hall element 51 which is detected by temperature sensor 74 passes through chopper circuit 78a and is input to one of the input terminals of multiplexer 76. The voltage corresponding to the temperature of shunt resistor 4 which is detected by temperature sensor 75 passes through chopper circuit 78b and is input to the other one of the input terminals of multiplexer 76. Either one of the input signals is selected and output by multiplexer 76, passes through chopper circuit 78c, and is input to amplifier 71. After amplification by amplifier 71, the signal passes through chopper circuits 78d and 78e and is input to analog-to-digital converter 72. After being converted into a digital signal sequence by analog-to-digital converter 72, the signals pass through chopper circuit 78f and are input to filter 73, where the signals are averaged and converted into parallel signals. Finally, the parallel signals pass through chopper circuit 78g and are output as a measurement value.

Chopper circuits 78a, 78b, and 78g chop the signal in synchronization with reference clock CK31 from clock distribution circuit 81 to globally reduce offsets that may arise mainly from the signal processing in temperature-measurement circuit 70. Chopper circuits 78c and 78d chop the differential signal in synchronization with reference clock CK32 from clock distribution circuit 81 to switch between positive and negative polarities, and chopper circuits 78e and 78f chop the differential signal in synchronization with reference clock CK33 from clock distribution circuit 81 to switch between positive and negative polarities, thereby respectively reducing 1/f noise that may arise mainly from the signal processing in amplifier 71 and analog-to-digital converter 72.

Signal processing circuit 60 is a processing circuit that corrects measurement values of first current-measurement circuit 10 and second current-measurement circuit 20, and detects anomalies in current-measurement semiconductor device 30, coreless magnetic sensor 50, and shunt resistor 4. Signal processing circuit 60 includes correctors 61 and 62, calculator 63, storage 64, comparer 65, anomaly detectors 66 to 68, and data interface (I/F) 69. Correctors 61 and 62, calculator 63, comparer 65, and anomaly detectors 66 to 68 are implemented by, for example, a gate array or a semiconductor memory that stores programs and a processor or the like that executes the programs. Storage 64 is implemented by, for example, semiconductor memory such as a static random-access memory (SRAM) or the like. Data I/F 69 is implemented by, for example, a logic circuit.

Storage 64 stores, in advance, temperature coefficients for correcting the temperature dependence of coreless magnetic sensor 50 and shunt resistor 4 obtained by temperature-measurement circuit 70, and stores correction parameters (a slope and an offset) calculated by calculator 63 for the measurement value of second current-measurement circuit 20.

Calculator 63 has a calibration mode in which the measurement value of second current-measurement circuit 20 that uses coreless magnetic sensor 50 is corrected based on the measurement value of first current-measurement circuit 10 that uses shunt resistor 4 and the resulting correction information (correction parameters indicating a slope and an offset) is stored in storage unit 64. Calculator 63 also has a normal measurement mode in which the stored correction information is transmitted to corrector 61 to enable correction of the measurement value of second current-measurement circuit 20 during current measurement. Moreover, in the normal measurement mode, calculator 63 reads, from storage 64, temperature coefficients corresponding to temperatures of coreless magnetic sensor 50 and shunt resistor 4 obtained by temperature-measurement circuit 70 and transmits the temperature coefficients to respective correctors 61 and 62, thereby enabling correction of the temperature dependence of the measurement values of first current-measurement circuit 10 and second current-measurement circuit 20.

Corrector 61 corrects the temperature dependence of the measurement value of second current-measurement circuit 20 that uses coreless magnetic sensor 50 based on a temperature coefficient transmitted from calculator 63, and further corrects the temperature-corrected measurement value based on correction information (correction parameters indicating a slope and an offset) transmitted from calculator 63.

Corrector 62 corrects the temperature dependence of the measurement value of first current-measurement circuit 10 that uses shunt resistor 4 based on a temperature coefficient transmitted from calculator 63.

In the normal measurement mode, comparer 65 compares a first measurement value obtained by corrector 62 after correcting the measurement value of first current-measurement circuit 10 with a second measurement value obtained by corrector 61 after correcting the measurement value of second current-measurement circuit 20, and transmits the comparison result to anomaly detector 67. More specifically, when the second measurement value obtained by corrector 61 after correcting the measurement value of second current-measurement circuit 20 that uses coreless magnetic sensor 50 falls within the range in which both coreless magnetic sensor 50 and shunt resistor 4 indicate valid measured currents, comparer 65 compares the first measurement value obtained by corrector 62 after correcting the measurement value of first current-measurement circuit 10 that uses shunt resistor 4 with the second measurement value obtained by corrector 61 after correcting the measurement value of second current-measurement circuit 20 that uses coreless magnetic sensor 50, and transmits the comparison result to anomaly detector 67.

Based on the comparison result transmitted from comparer 65, anomaly detector 67 outputs, when the first measurement value and the second measurement value do not agree within a certain range, an anomaly signal indicating that the first measurement value and the second measurement value do not agree within the certain range to data I/F 69. For example, based on the comparison result transmitted, anomaly detector 67 determines the occurrence of a short-mode failure in shunt resistor 4 when the first measurement value is lower than the second measurement value by more than a predetermined range, and outputs, to data I/F 69, an anomaly signal indicating the occurrence of a short-mode failure.

Anomaly detector 66 determines whether a second measurement value obtained by corrector 61 after correcting the measurement value of second current-measurement circuit 20 that uses coreless magnetic sensor 50 exceeds a predetermined normal operating-current range (i.e., the range of currents that typically flow during normal operation of measurement target device 3). When the second measurement value exceeds the normal operating-current range, anomaly detector 66 outputs, to data I/F 69, an anomaly signal indicating that the current value flowing through shunt resistor 4 in measurement target device 3 is abnormally high.

Likewise, anomaly detector 68 determines whether a first measurement value obtained by corrector 62 after correcting the measurement value of first current-measurement circuit 10 that uses shunt resistor 4 exceeds the predetermined normal operating-current range. When the first measurement value exceeds the normal operating-current range, anomaly detector 68 outputs, to data I/F 69, an anomaly signal indicating that the current value flowing through shunt resistor 4 in measurement target device 3 is abnormally high.

In synchronization with reference clock CK4 from clock distribution circuit 81, data I/F 69 transmits, to higher-level system 90, the first measurement value obtained by corrector 62 after correcting the measurement value of first current-measurement circuit 10, the second measurement value obtained by corrector 61 after correcting the measurement value of second current-measurement circuit 20 that uses coreless magnetic sensor 50, and anomaly signals output from anomaly detectors 66 to 68. Note that when data I/F 69 determines, by using at least one of the first measurement value or the second measurement value, that the current flowing through shunt resistor 4 falls within a predetermined micro-current region in which second current-measurement circuit 20 is unable to measure the current, data I/F 69 discards the measurement value of second current-measurement circuit 20 (i.e., does not transmit the measurement value to higher-level system 90), and outputs only the measurement value of first current-measurement circuit 10 (i.e., transmits the measurement value to higher-level system 90).

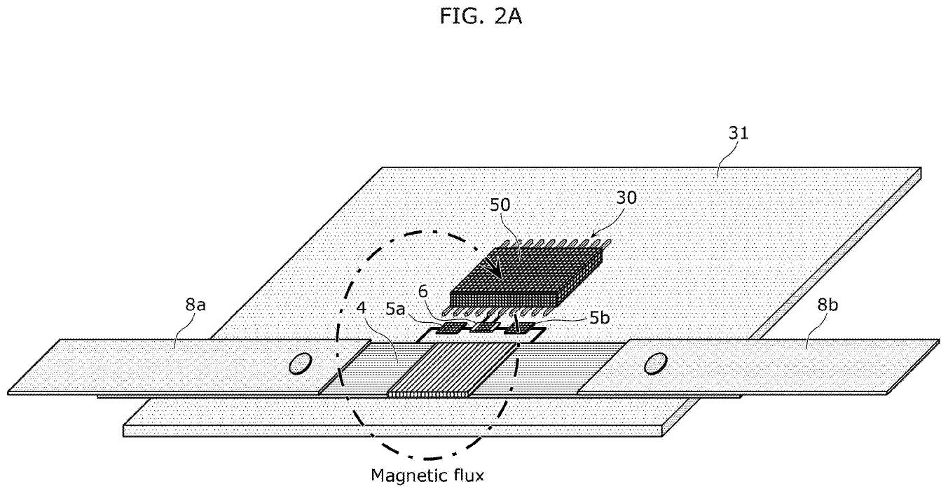

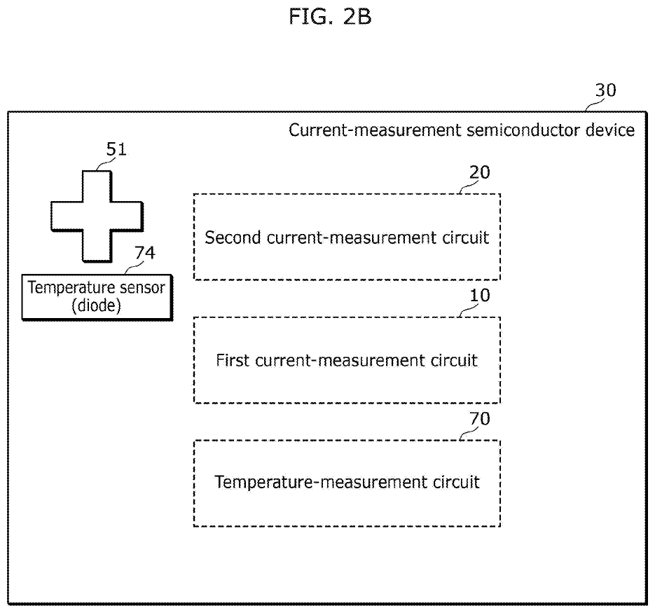

FIG. 2A is a diagram illustrating the external appearance of an implementation example of current-measurement semiconductor device 30 according to the embodiment. The diagram here illustrates an implementation example of current-measurement semiconductor device 30 implemented as a single-chip semiconductor or as a single semiconductor package on printed circuit board 31.

As shown by the present diagram, the top surface of printed circuit board 31 is provided with shunt resistor 4 whose ends are connected with bus bars 8a and 8b and filter circuit 5 (chip resistors 5a and 5b and chip capacitor 6) that is connected to shunt resistor 4 with a wiring pattern. Furthermore, current-measurement semiconductor device 30 that is connected to filter circuit 5 with a wiring pattern is mounted. Current-measurement semiconductor device 30 contains coreless magnetic sensor 50, and is provided in the vicinity of shunt resistor 4 with a small filter circuit 5 including chip components interposed therebetween. With this, the magnetic flux produced by the current flowing through shunt resistor 4 can be detected with high sensitivity by coreless magnetic sensor 50 contained in current-measurement semiconductor device 30. Note that the present diagram omits the illustration of temperature sensor 75 that detects the temperature of shunt resistor 4.

FIG. 2B is a diagram illustrating a layout example of main circuit elements in the current-measurement semiconductor device 30 according to the embodiment. In this layout example, a diode, which is one example of temperature sensor 74, is provided in contact with or in the vicinity of Hall element 51. Since the forward voltage of the diode such as a silicon (Si) diode or the like has a certain negative temperature coefficient, the temperature can be measured by measuring the voltage across the diode.

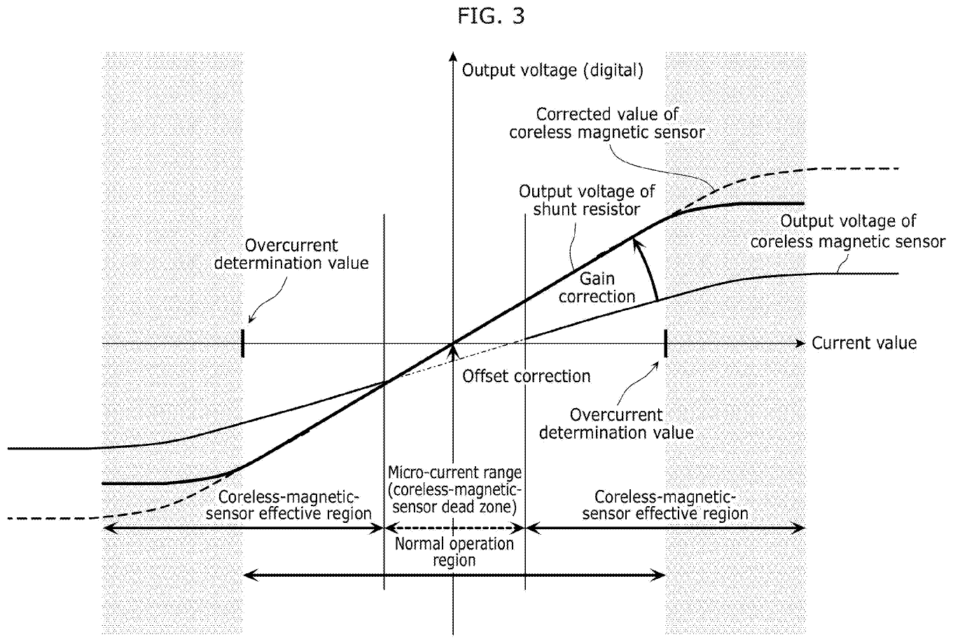

FIG. 3 is a diagram illustrating current-voltage characteristics of shunt resistor 4 included in measurement target device 3 and coreless magnetic sensor 50 included in current-measurement semiconductor device 30, and corrections performed by current-measurement semiconductor device 30. The horizontal axis represents the current flowing through shunt resistor 4 which is to be detected, and the vertical axis represents the output voltages from shunt resistor 4 and coreless magnetic sensor 50.

In the horizontal axis, the “micro-current range” indicates a current range (“coreless-magnetic-sensor dead zone”) in which coreless magnetic sensor 50 is unable to correctly detect the current, and the “coreless-magnetic-sensor effective region” indicates a current range in which coreless magnetic sensor 50 can detect a valid current value. The “normal operation region” indicates a range of currents (also referred to as “normal operating-current range”) that typically flow during normal operation of measurement target device 3, and is used to determine the presence or absence of anomalies in measurement target device 3.

In the present diagram, the thick solid line denotes the current-voltage characteristics of shunt resistor 4. The current-voltage characteristics exhibit linearity over a wide current range including the “normal operation region,” but exhibit saturation characteristics in an extremely high current range due to the dynamic range limit of the measurement circuit.

In the present diagram, the dotted-and-dashed line and the following narrow solid line denotes the current-voltage characteristics of coreless magnetic sensor 50. The dotted-and-dashed line denotes the current-voltage characteristics of coreless magnetic sensor 50 in the “micro-current region” in which coreless magnetic sensor 50 is unable to accurately detect the current.

In the present diagram, the dashed line that partially overlaps the thick solid line denotes the current-voltage characteristics of coreless magnetic sensor 50 that has been corrected using shunt resistor 4. Originally, as shown by the dotted-and-dashed line and the following narrow solid line, the current-voltage characteristics of coreless magnetic sensor 50 have a slope smaller than the slope of shunt resistor 4 and exhibit an output-voltage offset when the current value indicates zero. For this reason, calculator 63 of signal processing circuit 60 included in current-measurement semiconductor device 30 according to the present embodiment records the measurement value of first current-measurement circuit 10 that uses shunt resistor 4 and the measurement value of second current-measurement circuit 20 that uses coreless magnetic sensor 50 when the current flowing through shunt resistor 4 is within the “normal operation region” and the “coreless-magnetic-sensor effective region” (the current value at two or more different locations), and calculates the relationship of the measurement values using a first-order approximation or the like, thereby enabling application of “gain correction” and “offset correction” to the measurement value of second current-measurement circuit 20 that uses coreless magnetic sensor 50 (i.e., enabling the use of the corrected current-voltage characteristics of coreless magnetic sensor 50 as indicated by the dashed line that partially overlaps the thick solid line). In other words, corrector 61 of signal processing circuit 60 can output a corrected measurement value of second current-measurement circuit 20 that uses coreless magnetic sensor 50 by using the corrected current-voltage characteristics of coreless magnetic sensor 50.

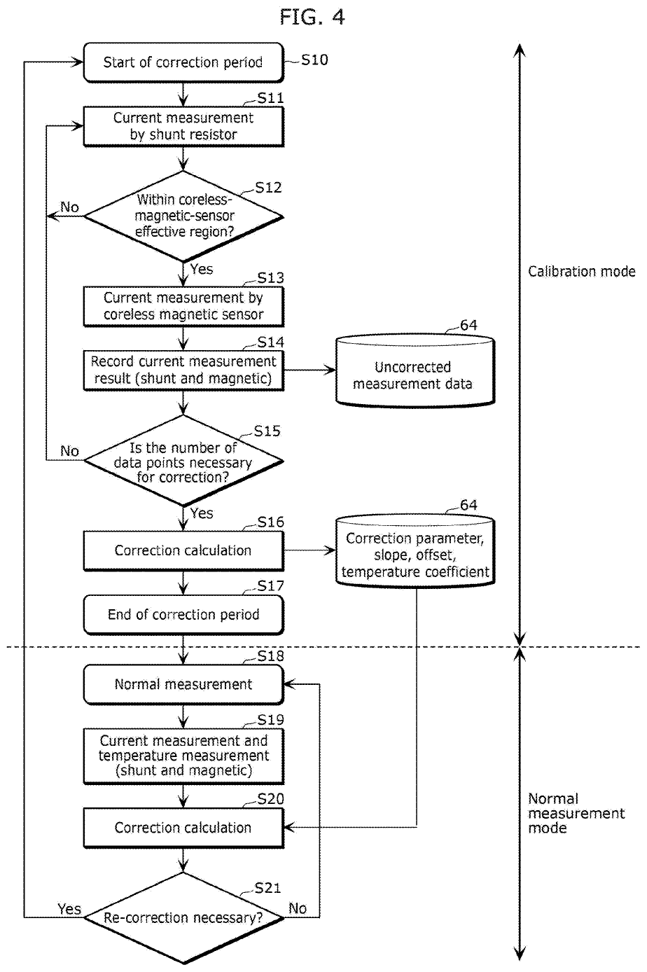

FIG. 4 is a flowchart illustrating operation performed by current-measurement semiconductor device 30 according to the embodiment. The flowchart here mainly shows operation for correction processing performed by calculator 63 of signal processing circuit 60 included in current-measurement semiconductor device 30 (i.e., correction of the measurement value of second current-measurement circuit 20 using the measurement value of first current-measurement circuit 10, and correction of the temperature dependence of coreless magnetic sensor 50 and shunt resistor 4).

The operation of current-measurement semiconductor device 30 includes a calibration mode (S10 to S17) and a normal measurement mode (S18 to S21) that follows the calibration mode. Note that the calibration mode may be performed on a manufactured current-measurement semiconductor device 30 prior to shipment from a manufacturing company or may be performed after being placed into operation after the shipment.

In the calibration mode (S10 to S17), calculator 63 of signal processing circuit 60 obtains the measurement value measured by first current-measurement circuit 10 using shunt resistor 4 in the first place (S11).

Next, calculator 63 determines whether the obtained measurement value falls within the “normal operation region” and the “coreless-magnetic-sensor effective region” shown in FIG. 3 (S12). When the determination is negative (No in S12), calculator 63 returns to step S11 and repeats the process. Alternatively, when the determination is positive (Yes in S12), calculator 63 further obtains the measurement value of second current-measurement circuit 20 that uses coreless magnetic sensor 50 (S13), and accumulates those measurement values in storage 64 as uncorrected measurement data (S14).

Next, calculator 63 determines whether the number of data points necessary for correction has been obtained (S15). When the determination is negative (No in S15), calculator 63 returns to step S11 and repeats the processes. Alternatively, when the determination is positive (Yes in S15), calculator 63 uses the stored uncorrected measurement data accumulated in storage 64 to date to calculate the relationship of the uncorrected measurement data using a first-order approximation or the like, and then calculates correction parameters (a slope and an offset) that enable application of “gain correction” and “offset correction” to the measurement value of second current-measurement circuit 20 that uses coreless magnetic sensor 50, and finally stores the parameters in storage 64 (S16).

Note that storage 64 stores, in advance, temperature coefficients for correcting the temperature dependence of coreless magnetic sensor 50 and shunt resistor 4. Therefore, in the calibration mode from the above steps S10 to S17, measurement values obtained after temperature correction may be used as the measurement values of first current-measurement circuit 10 and second current-measurement circuit 20.

Next, in the normal measurement mode (S18 to S21), calculator 63 of signal processing circuit 60 obtains, in the first place, the measurement value from each of first current-measurement circuit 10 that uses shunt resistor 4 and second current-measurement circuit 20 that uses coreless magnetic sensor 50, and obtains temperatures of coreless magnetic sensor 50 and shunt resistor 4 from temperature-measurement circuit 70 (S19).

Thereafter, calculator 63 reads, from storage 64, temperature coefficients corresponding to the obtained temperatures of coreless magnetic sensor 50 and shunt resistor 4 and transmits the temperature coefficients to respective correctors 61 and 62, thereby enabling corrector 61 to correct the temperature dependence of the measurement value of second current-measurement circuit 20 and corrector 62 to correct the temperature dependence of the measurement value of first current-measurement circuit 10. Calculator 63 further reads, from storage 64, correction information (correction parameters indicating a slope and an offset) and transmits the correction information to corrector 61, thereby enabling corrector 61 to apply “gain correction” and “offset correction” to the measurement value of second current-measurement circuit 20 that uses coreless magnetic sensor 50 (S20).

Next, calculator 63 determines whether a re-correction is necessary by, for example, determining whether a predetermined period has elapsed since the last execution of the calibration mode (S21). When the determination is positive (Yes in S21), calculator 63 returns to the calibration mode (S10 to S17) and repeats the processes. Alternatively, when the determination is negative (No in S21), calculator 63 returns to the normal measurement mode (S18 to S21) and repeats the processes.

As has been described above, current-measurement semiconductor device 30 according to the embodiment corrects the measurement value of second current-measurement circuit 20 using the measurement value of first current-measurement circuit 10 and corrects the temperature dependence of coreless magnetic sensor 50 and shunt resistor 4. With this, current-measurement semiconductor device 30 that is designed with redundancy to avoid occurrences of common-cause failures enables highly accurate current measurement.

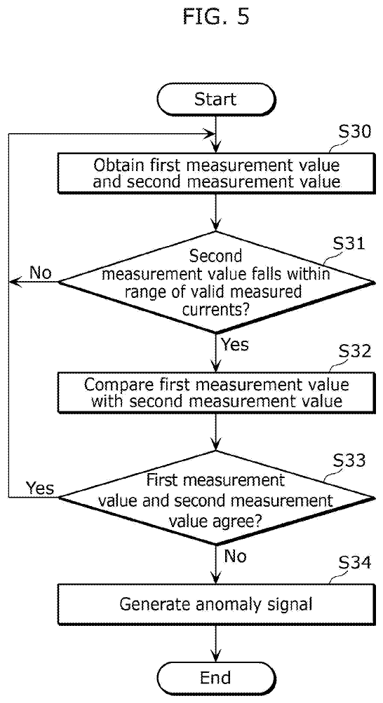

FIG. 5 is a flowchart illustrating operation performed by current-measurement semiconductor device 30 according to the embodiment for detecting an anomaly in shunt resistor 4. The flowchart here mainly shows processing performed by comparer 65 and anomaly detector 67 of signal processing circuit 60 included in current-measurement semiconductor device 30 for detecting an anomaly in shunt resistor 4.

Comparer 65 obtains a first measurement value obtained by corrector 62 after correcting the measurement value of first current-measurement circuit 10 that uses shunt resistor 4 in the normal measurement mode and a second measurement value obtained by corrector 61 after correcting the measurement value of second current-measurement circuit 20 that uses coreless magnetic sensor 50 in the normal measurement mode (S30).

Thereafter, comparer 65 determines whether the obtained second measurement value falls within the range in which both coreless magnetic sensor 50 and shunt resistor 4 indicate valid measured currents (S31). When the determination is negative (No in S31), comparer 65 returns to step S30 and repeats the process. Alternatively, when the determination is positive (Yes in S31), comparer 65 compares the obtained first measurement value with the obtained second measurement value, and transmits the comparison result to anomaly detector 67 (S32).

Based on the comparison result transmitted from comparer 65, anomaly detector 67 determines whether the first measurement value and the second measurement value agree within a certain range (S33). When the determination is positive (Yes in S33), anomaly detector 67 determines that there is no anomaly, and returns to step S30 to repeat the processes. Alternatively, when the determination is negative (No in S33), anomaly detector 67 generates an anomaly signal indicating the negative result (S34) and transmits the anomaly signal to higher-level system 90 via data I/F 69. For example, based on the comparison result transmitted, anomaly detector 67 determines the occurrence of a short-mode failure in shunt resistor 4 when the first measurement value is lower than the second measurement value by more than a predetermined range, and outputs an anomaly signal indicating the occurrence of a short-mode failure.

As has been described above, current-measurement semiconductor device 30 according to the embodiment compares the measurement value of first current-measurement circuit 10 with the corrected measurement value of second current-measurement circuit 20 to detect a short-mode failure in shunt resistor 4, thereby ensuring safe operation.

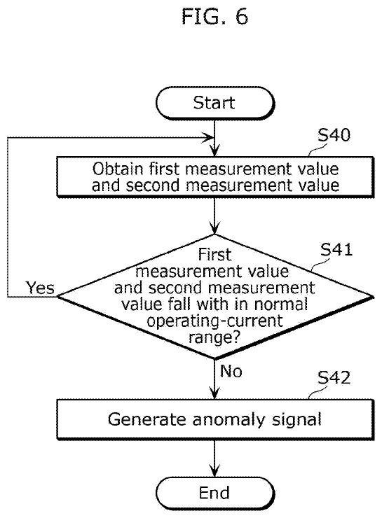

FIG. 6 is a flowchart illustrating operation performed by current-measurement semiconductor device 30 according to the embodiment for detecting an anomaly in measurement target device 3. The flowchart here mainly shows processing performed by anomaly detectors 68 and 66 of signal processing circuit 60 included in current-measurement semiconductor device 30 for detecting an anomaly in the current value of measurement target device 3.

First, anomaly detectors 68 and 66 respectively obtain a first measurement value obtained by corrector 62 after correcting the measurement value of first current-measurement circuit 10 that uses shunt resistor 4 and a second measurement value obtained by corrector 61 after correcting the measurement value of second current-measurement circuit 20 that uses coreless magnetic sensor 50 (S40).

Thereafter, anomaly detectors 68 and 66 respectively determine whether the obtained first measurement value and the obtained second measurement value fall within a predetermined normal operating-current range (i.e., the range of currents that typically flow during normal operation of measurement target device 3) (S41).

When both anomaly detectors 66 and 68 provide positive determination (i.e., both the first measurement value and the second measurement value fall within the predetermined normal operating-current range) (Yes in S41), anomaly detectors 66 and 68 determine that there is no anomaly, and return to step S40 to repeat the processes. Alternatively, when the determination is negative (i.e., at least one of the first measurement value or the second measurement value fails to fall within the predetermined normal operating-current range) (No in S41), an anomaly signal is generated which indicates that the current value flowing through shunt resistor 4 in measurement target device 3 is abnormally high (S42) and the anomaly signal is then transmitted to higher-level system 90 via data I/F 69. With this, a circuit breaker (not illustrated) connected in series with cell stack 3a is caused to operate to interrupt the current flowing through shunt resistor 4.

As has been described above, current-measurement semiconductor device 30 according to the embodiment compares the first and the second measurement values with the normal operating-current range to detect that abnormally high current is flowing through measurement target device 3, thereby ensuring safe operation of measurement target device 3.

As stated above, current-measurement semiconductor device 30 according to technique 1 of the present embodiment is a current-measurement semiconductor device that measures current flowing through shunt resistor 4 included in measurement target device 3. Current-measurement semiconductor device 30 includes first current-measurement circuit 10 that measures the current flowing through shunt resistor 4 by detecting a voltage across shunt resistor 4, and second current-measurement circuit 20 that includes coreless magnetic sensor 50, and measures the current flowing through shunt resistor 4 using coreless magnetic sensor 50.

Accordingly, current-measurement semiconductor device 30 according to the embodiment is a single semiconductor device that measures the current flowing through shunt resistor 4, and includes coreless magnetic sensor 50 that can perform measurement in higher current regions without suffering from magnetic saturation due to a magnetic core. Moreover, since current-measurement semiconductor device 30 is configured as a single semiconductor device that can be provided in the vicinity of shunt resistor 4, it is possible to implement a current-measurement semiconductor device that can reduce common-cause failures.

Moreover, current-measurement semiconductor device 30 according to technique 2 further includes reference clock generation circuit 80, in addition to the configuration of current-measurement semiconductor device 30 according to technique 1. First current-measurement circuit 10 and second current-measurement circuit 20 respectively include chopper circuits 18a to 18f and chopper circuits 28a to 28e that operate in synchronization with reference clocks generated by reference clock generation circuit 80. With this, sources of errors such as offsets and 1/f noise that may arise in first current-measurement circuit 10 and second current-measurement circuit 20 are reduced, thereby enabling highly accurate current measurement.

Furthermore, current-measurement semiconductor device 30 according to technique 3 further includes temperature sensors 74 and 75 that respectively detect temperatures of coreless magnetic sensor 50 and shunt resistor 4, and signal processing circuit 60 that corrects temperature dependence of first current-measurement circuit 10 and second current-measurement circuit 20 based on the temperatures detected by temperature sensors 74 and 75, in addition to the configuration of current-measurement semiconductor device 30 according to technique 1 or 2. With this, the temperature dependence of coreless magnetic sensor 50 and shunt resistor 4 is corrected, thereby enabling highly accurate current measurement.

Moreover, current-measurement semiconductor device 30 according to technique 4 further includes signal processing circuit 60 that corrects a measurement value of second current-measurement circuit 20, using a measurement value of first current-measurement circuit 10, in addition to the configuration of current-measurement semiconductor device 30 according to any of techniques 1 to 3.

Furthermore, current-measurement semiconductor device 30 according to technique 5 is current-measurement semiconductor device 30 according to any of techniques 1 to 4. In such current-measurement semiconductor device 30, signal processing circuit 60 has (i) a calibration mode in which the measurement value of second current-measurement circuit 20 is corrected using the measurement value of first current-measurement circuit 10 and correction information obtained is stored and (ii) a normal measurement mode in which current measurement is performed using a corrected measurement value of second current-measurement circuit 20, the corrected measurement value being obtained by correcting the measurement value of second current-measurement circuit 20 based on the correction information stored. In the normal measurement mode, the measurement value of first current-measurement circuit 10 is compared with the corrected measurement value of second current-measurement circuit 20 to detect an anomaly in shunt resistor 4. With this, the measurement value of second current-measurement circuit 20 can be corrected using the measurement value of first current-measurement circuit 10. Furthermore, agreement between the two measurement values is checked, thereby enabling detection of a short-mode failure in shunt resistor 4.

In addition, current-measurement semiconductor device 30 according to technique 6 is current-measurement semiconductor device according to any of techniques 1 to 5. In such current-measurement semiconductor device 30, when either one of the measurement value of first current-measurement circuit 10 or the corrected measurement value of second current-measurement circuit 20 exceeds a predetermined normal operating-current range, signal processing circuit 60 detects that measurement target device 3 has an anomaly. With this, abnormally high current that flows through measurement target device 3 is detected, thereby ensuring safe operation of measurement target device 3.

Moreover, current-measurement semiconductor device 30 according to technique 7 is current-measurement semiconductor device 30 according to any of techniques 1 to 6. In such current-measurement semiconductor device 30, signal processing circuit 60, in a predetermined micro-current region in which second current-measurement circuit 20 is unable to measure the current, discards the measurement value of second current-measurement circuit 20 and outputs the measurement value of first current-measurement circuit 10. With this, the measurement value of second current-measurement circuit 20 that exhibits low accuracy in the micro-current region is discarded, and thus only valid measurement value is output for all current regions.

Note that, in current-measurement semiconductor device 30 according to any of techniques 1 to 7, coreless magnetic sensor 50 may be a Hall element or a magnetoresistive element.

Hereinbefore, current-measurement semiconductor device 30 according to the present disclosure has been described based on the embodiment, but the present disclosure is not limited to the embodiment. The scope of the present disclosure encompasses embodiments as a result of making, to the embodiment, various modifications that may be conceived by those skilled in the art, and different embodiments achieved by combining some elements in the embodiments, as long as the resultant embodiments do not depart from the spirit of the present disclosure.

For example, Hall element 51 is used as coreless magnetic sensor 50 in the above-described embodiment, but is not limited thereto. A highly sensitive magnetoresistive (MR) element or a giant magnetoresistive (GMR) element may be formed on the substrate surface of current-measurement semiconductor device 30 using thin-film formation techniques.

Moreover, in the above-described embodiment, temperature sensor 75 for detecting the temperature of shunt resistor 4 is provided outside a single-chip semiconductor or a semiconductor package forming current-measurement semiconductor device 30, but the configuration is non-limiting. Temperature sensor 75 may be provided inside the single-chip semiconductor or the semiconductor package forming current-measurement semiconductor device 30.

In addition, in the above-described embodiment, filter circuit 5 is mounted on printed circuit board 31 as a circuit different from current-measurement semiconductor device 30, but the configuration is non-limiting. Filter circuit 5 may be integrated into current-measurement semiconductor device 30 as a circuit included in current-measurement semiconductor device 30.

Furthermore, in the above-described embodiment, shunt resistor 4 is included in measurement target device 3, but the configuration is non-limiting. Shunt resistor 4 may be a circuit element included in current-measurement semiconductor device 30.

Moreover, the present disclosure can be implemented not only as a current-measurement semiconductor device but also as (i) a method relating to processing (processing shown by the flowcharts in FIG. 4 to FIG. 6) performed by a signal processing circuit included in the current-measurement semiconductor device (e.g., a method for correcting the temperature dependence of the first current-measurement circuit and the second current-measurement circuit and a method for detecting an anomaly in the shunt resistor), (ii) a program causing a processor to execute the method, (iii) a computer-readable recording medium on which such a program is recorded, or (iv) a program product including such a program.

Although only an exemplary embodiment of the present disclosure has been described in detail above, those skilled in the art will readily appreciate that many modifications are possible in the exemplary embodiment without materially departing from the novel teachings and advantages of the present disclosure. Accordingly, all such modifications are intended to be included within the scope of the present disclosure.

### INDUSTRIAL APPLICABILITY

Mainly for current measurement of lithium-ion batteries for electric vehicles, the present disclosure, as a current-measurement semiconductor device that measures a current flowing through a shunt resistor included in a measurement target device, uses a current-measurement circuit capable of measuring the current using the shunt resistor with high accuracy and a high dynamic range, and enables easy implementation of redundancy using a coreless magnetic sensor that reduces common-cause failures in terms of functional safety. Highly accurate current measurement by the shunt resistor enables highly accurate calculation of the state of charge (SOC) or the state of health (SOH) of lithium-ion batteries for electric vehicles, thereby extending the driving range of the electric vehicle.

1. A current-measurement semiconductor device that measures current flowing through a shunt resistor included in a measurement target device, the current-measurement semiconductor device comprising:
a first current-measurement circuit that measures the current flowing through the shunt resistor by detecting a voltage across the shunt resistor; and
a second current-measurement circuit that includes a coreless magnetic sensor, and measures the current flowing through the shunt resistor using the coreless magnetic sensor.

2. The current-measurement semiconductor device according to claim 1, further comprising:
a reference clock generation circuit, wherein
each of the first current-measurement circuit and the second current-measurement circuit includes a chopper circuit that operates in synchronization with a reference clock generated by the reference clock generation circuit.

3. The current-measurement semiconductor device according to claim 1, further comprising:
temperature sensors that detect temperatures of the coreless magnetic sensor and the shunt resistor; and
a signal processing circuit that corrects temperature dependence of the first current-measurement circuit and the second current-measurement circuit, based on the temperatures detected by the temperature sensors.

4. The current-measurement semiconductor device according to claim 1, further comprising:
a signal processing circuit that corrects a measurement value of the second current-measurement circuit, using a measurement value of the first current-measurement circuit.

5. The current-measurement semiconductor device according to claim 4, wherein
the signal processing circuit has (i) a calibration mode in which the measurement value of the second current-measurement circuit is corrected using the measurement value of the first current-measurement circuit and correction information obtained is stored and (ii) a normal measurement mode in which current measurement is performed using a corrected measurement value of the second current-measurement circuit, the corrected measurement value being obtained by correcting the measurement value of the second current-measurement circuit based on the correction information stored, and in the normal measurement mode, the measurement value of the first current-measurement circuit is compared with the corrected measurement value of the second current-measurement circuit to detect an anomaly in the shunt resistor.

6. The current-measurement semiconductor device according to claim 5, wherein
when either one of the measurement value of the first current-measurement circuit or the corrected measurement value of the second current-measurement circuit exceeds a predetermined normal operating-current range, the signal processing circuit detects that the measurement target device has an anomaly.

7. The current-measurement semiconductor device according to claim 4, wherein
in a predetermined micro-current region in which the second current-measurement circuit is unable to measure the current, the signal processing circuit discards the measurement value of the second current-measurement circuit and outputs the measurement value of the first current-measurement circuit.

8. The current-measurement semiconductor device according to claim 1, wherein
the coreless magnetic sensor is a Hall element.

9. The current-measurement semiconductor device according to claim 1, wherein the coreless magnetic sensor is a magnetoresistive element.
